(19) United States
(12) Patent Application Publication
(10) Pub. No.: US 2004/0008491 A1
(43) Pub. Date: Jan. 15, 2004

(54) Heat dissipation apparatus

(76) Inventor: Yung-Shun Chen, Taoyuan (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/294,279

(22) Filed: Nov. 14, 2002

(30) Foreign Application Priority Data
Jul. 11, 2002 (TW) 91210557

(51) Int. Cl. H05K 7/20

(52) U.S. Cl. 361/700; 174/15.2; 62/3.3

(57) ABSTRACT

A heat dissipation apparatus. The heat dissipation apparatus includes a thermal plate, a thermal block, a heat pipe, and a thermal body. The thermal plate and the thermal block are joined by rivets through the corresponding holes.

### BACKGROUND OF THE INVENTION

1. Field of the Invention

The present invention relates to a heat dissipation apparatus, and in particular to a heat dissipation apparatus assembled by riveting.

2. Description of the Related Art

As popularity of electronic products has grown, size and weight have been reduced. With the progress of CPU efficiency and increased functions of peripheral devices, heat dissipation has become more and more important. However, while the size has reduced, Electromagnetic Interference (EMI) generated by electric components inside is considerable, greatly affecting performance.

Generally speaking, heat dissipation devices include a thermal plate and a thermal block. The conventional method of joining the thermal plates and the thermal blocks is by screwing or welding. However, screwing requires additional parts and manpower during production. Welding also has similar problems. Moreover, screwing and welding are not ideal joining techniques to avoid EMI.

### SUMMARY OF THE INVENTION

An object of the invention is to provide a heat dissipation apparatus for a electrical product which can effectively restrain EMI. The electrical product has a heat source inside. The heat dissipation apparatus comprises a thermal plate, a thermal block, a heat pipe, a thermal body and a plurality of fins. The thermal plate is a thin metal plate including a plurality of first joined portions. The thermal block is disposed on the thermal plate, which includes a plurality of second joined portions. The heat pipe is disposed on the thermal plate, which passes through the thermal block and connects to the thermal body. The heat is transferred through the heat pipe to the thermal body and dissipated via the fins disposed thereon. Furthermore, each first joined portion comprises a rivet and each second joined portion comprises a through hole. The thermal plate and the thermal block are joined by inserting the rivets through the corresponding holes, and the rivets are hammered on the other side of the through holes.

### BRIEF DESCRIPTION OF THE DRAWINGS

The present invention can be more fully understood by reading the subsequent detailed description and examples with references made to the accompanying drawings, wherein:

FIG. 1 is a perspective diagram of a heat dissipation apparatus in accordance with the present invention;

FIG. 2 is a sectional view of the riveting mechanism before assembly in accordance with the present invention;

FIG. 3 is a sectional view of the riveting mechanism after assembly in accordance with the present invention;

### DETAILED DESCRIPTION OF THE INVENTION

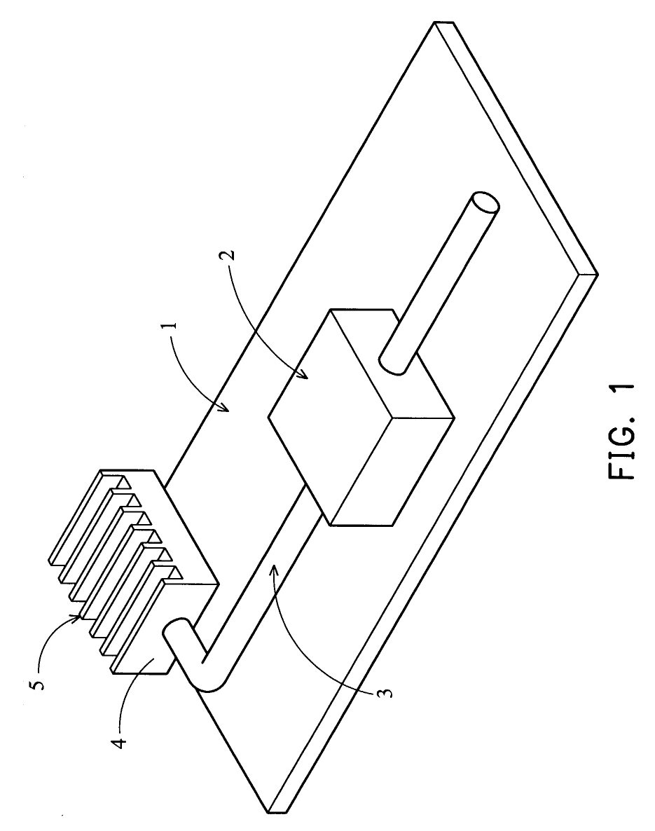

Referring to FIG. 1, the heat dissipation apparatus comprises a thermal plate 1, a thermal block 2, a heat pipe 3, a thermal body 4, and a plurality of fins 5. The thermal plate 1 is metal with high thermal conductivity. Thus, heat can be efficiently dissipated. The thermal block 2 is disposed on the thermal plate 1, also metal with high thermal conductivity (e.g. aluminum). The heat pipe 3 and the thermal body 4 are disposed on the thermal plate 1, and a plurality of fins 5 is disposed on the thermal body 4. The heat pipe 3 passes through the thermal block 2 and connect to the thermal body 4. Therefore, the heat can be transferred through the heat pipe 3 to the thermal body 4 and dissipated via the fins 5 thereon.

The heat source (not shown) inside the electrical product may be a CPU or other electric component that generates heat and adheres to the surface of the thermal block 2 (ordinarily the upper surface in FIG. 1). Thus, the heat is conducted through the thermal block 2 and dissipated in two ways, directly conducted to the thermal plate 1 and dissipated via the large-area surface thereon, or transferred through the heat pipe 3, wherein the working fluid inside can efficiently bring the heat to the thermal body 4, and the heat is dissipated via the fins 5.

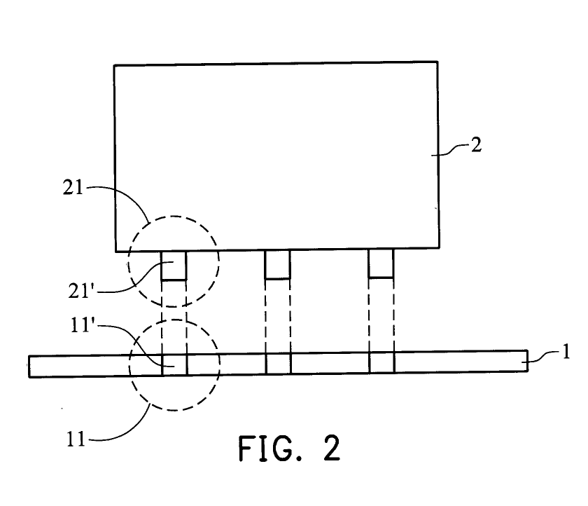

Referring to FIG. 2, the thermal plate 1 of the present invention includes a plurality of first joined portions 11, and each first joined portion 11 comprises a through hole 11′. The thermal block 2 includes a plurality of second joined portions 21, and each second joined portion 21 comprises a rivet 21′.

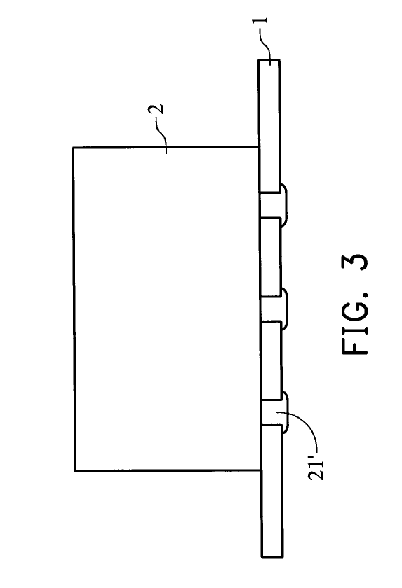

Referring to FIG. 3, the rivets 21′ are inserted through the corresponding holes 11′ in the thermal plate 1. Subsequently the rivets 21′ are hammered on the other side of the through holes 11′ so that the thermal plate 1 and the thermal block 2 are joined.

Since the riveting technique is utilized, the present invention can effectively restrain EMI in the electrical product. Furthermore, riveting also has the advantages of accurate positioning, tight joining, and equals the performance of the prior art. Therefore the present invention has value and practicability.

While the invention has been described by way of examples and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat dissipation apparatus, comprising:
a thermal plate with a rivet; and
a thermal block with a through part for receiving the rivet;
wherein the thermal plate and the thermal block are joined by riveting the rivet and the through part.

2. The heat dissipation apparatus as claimed in claim 1, further comprising a heat pipe disposed on the thermal plate and passing through the thermal block.

3. The heat dissipation apparatus as claimed in claim 2, further comprising a thermal body disposed on the thermal plate and connected to the heat pipe.

4. The heat dissipation apparatus as claimed in claim 1, wherein the thermal block adheres to a device generating heat.

5. The heat dissipation apparatus as claimed in claim 4, wherein the device is a CPU.

6. The heat dissipation apparatus as claimed in claim 1, wherein the thermal plate is made of aluminum.

7. A heat dissipation apparatus comprising:
a thermal plate with a first joining portion;
a thermal block with a second joining portion corresponding to the first joining portion; and
a rivet means for fixing the first joining portion and the second joining portion together.
